(19) United States
(12) Patent Application Publication
(10) Pub. No.: US 2020/0185577 A1
(43) Pub. Date: Jun. 11, 2020

(54) LED LIGHT SOURCE DEVICE AND MANUFACTURING METHOD THEREOF

(71) Applicant: Xiamen Britesun Technology Co., Ltd., Xiamen (CN)

(72) Inventors: Yan JIANG, Xiamen (CN); Puming JIANG, Xiamen (CN); Yanhui ZHANG, Xiamen (CN); Ziyang HE, Xiamen (CN)

(73) Assignee: Xiamen Britesun Technology Co., Ltd., Xiamen (CN)

(21) Appl. No.: 16/349,563

(22) PCT Filed: Apr. 23, 2018
(86) PCT No.: PCT/CN2018/084029

§ 371 Date: May 13, 2019

(30) Foreign Application Priority Data
Sep. 29, 2017 (CN) 201710907508.3

(51) Int. Cl. H01L 33/56; H01L 33/58; F21K 9/64; F21K 9/90

(52) U.S. Cl. CPC H01L 33/56; H01L 33/58; F21K 9/64; H01L 33/507; H01L 2933/005; H01L 2933/0058; F21K 9/90

(57) ABSTRACT

The present application discloses an LED light source device and a manufacturing method thereof. Methyl-based silica gel or phenyl-based silica gel is blended with a light diffusion agent or a mixed powder of a light diffusion agent and a phosphor at an amount of 2% to 8% by weight to form a novel colloid, which is coated on a blue light chip fixed in the form of SMD or COB to form an LED light source device. The light output efficiency thereof reaches more than 92% of the light output efficiency of a light source device not coated with any colloid (that is, the blue light chip is exposed), and is 20% higher than the light output efficiency of a light source device coated with methyl-based silica gel or phenyl-based silica gel.

### CROSS REFERENCE OF RELATED APPLICATION

This application is a US application for PCT international application No. PCT/CN2018/084029, filed on Apr. 23, 2018, which claim priority to Chinese Application No. 201710907508.3, filed on Sep. 29, 2017. The entire contents of this international application are incorporated herein by reference.

### TECHNICAL FIELD

The present application relates to the field of lighting devices, and especially to a colloid, an LED light source device, and a manufacturing method thereof.

### BACKGROUND

At present, LED devices in which the blue light chip emits blue light having a wavelength of 450 to 460 nm to excite the phosphor to generate white light are mainly formed in three modes. The first one is SMD. That is, a blue light chip is fixed (die bonded) on a specific bracket, and then connected to electrodes via gold wires. A phosphor gel is then directly coated on the blue light chip and solidified. After the gel is solidified, an LED light source device unit packaged in the form of SMD is formed. The second one is COB. The blue light chip is directly fixed on a heat conductive metal plate or a heat conductive ceramic substrate (also referred to as a heat sink), and then the phosphor gel is directly coated and solidified on the blue light chip, and the metal or ceramic substrate, and after the gel solidification is finished, a LED light source device unit in the form of COB is formed. The third one is a remote phosphor excitation mode. The blue light chip is fixed on the specific bracket described in the first SMD mode or the heat sink substrate described in the second COB mode. A transparent colloid (such as phenyl-based silica gel, phenyl-based silica gel, epoxy resin, etc.) is then coated and solidified to form an LED light source device. The LED light source device is covered by a component (such as a lampshade, hereinafter referred to as a remote phosphor lampshade) added with phosphor, and mounted with a driving circuit and the like to form an LED lamp. The blue light chip emits blue light (having a wavelength of 450 to 460 nm) that directly illuminates the component (such as a dome) added with phosphor to make it emit white light. In this mode, the phosphor is not directly coated on the blue LED chip, and there is a certain distance between the phosphor and the LED chip, so it is called a remote excitation mode.

In the light source devices packaged in the forms of SMD and COB as described above, since the phosphor is directly coated on the blue light chip, two times of heat generation during the operating process result in a higher operating temperature of the light source device. The temperature of the phosphor surface layer can reach more than 150 degrees Celsius. Phosphor is not a long-periodic high temperature-resistant material, and particularly has a photon thermal quenching effect. The higher the operating temperature is, the lower the efficiency of converting blue light into white light will be. At the same time, phosphor is attenuated seriously in the case of long-term operation at high temperatures. Although the remote excitation mode has advantages such as small phosphor photon thermal quenching effect, low temperature, weak light attenuation, long lift time, and the like, it is not extensively used in practical applications because the overall luminous efficiency of a luminaire is not high, resulting in a high cost. Why the luminous efficiency of a luminaire in the remote mode is lower? The applicant found that this is due to a low blue light output efficiency of the light source device used in such a system. The reason for the low blue light output efficiency is that partial blue light undergoes total reflection after phenyl-based silica gel or phenyl-based silica gel is coated.

### SUMMARY

The object of the present application is to provide a transparent colloid instead of the original transparent colloid to be coated on the blue light chip fixed in the form of SMD or COB to form a novel LED light source device, which can reduce total reflection of light without increasing the temperature of the chip so as to enhance the blue light output efficiency.

The following technical solutions seek to solve the technical problem to be solved by the present application.

In an aspect, an LED light source device is provided, comprising a blue light chip fixed on a substrate and a colloid solidified on the blue light chip, and the colloid comprises silica gel base and light diffusion agent at an amount of 2% to 8% by weight.

In an optional embodiment, the light diffusion agent has a particle diameter D50 of less than 10 μm and a refractive index of 1.5 to 1.7.

In an optional embodiment, the silica gel base comprises methyl-based silica gel or phenyl-based silica gel.

In an optional embodiment, a remote phosphor lampshade is provided outside the LED light source device.

In another aspect, a LED light source device is provided, comprising a blue light chip fixed on a substrate and a colloid solidified on the blue light chip, and the colloid is made by silica gel base and a mixed powder at an amount of 2% to 8% by weight, the mixed powder comprising light diffusion agent and LED phosphor.

In an optional embodiment, the light diffusion agent has a particle diameter D50 of less than 10 μm and a refractive index of 1.5 to 1.7.

In an optional embodiment, the silica gel base comprises methyl-based silica gel or phenyl-based silica gel.

In an optional embodiment, a remote phosphor lampshade is provided outside the LED light source device.

In another aspect, a method for manufacturing an LED light source device, comprising the following steps:

fixing a blue light chip on a substrate in the form of SMD or COB,

coating a colloid on the blue light chip, which colloid comprising silica gel base and light diffusion agent at an amount of 2% to 8% by weight, and

solidifying the colloid to form an LED light source device.

The light output efficiency of the LED light source device of this application reaches more than 92% of the light output efficiency of a light source device not coated with any colloid (that is, the blue light chip is exposed), and is 20% higher than the light output efficiency of a light source device coated with methyl-based silica gel or phenyl-based silica gel.

### BRIEF DESCRIPTION OF THE DRAWINGS

The drawings are included to provide a further understanding of the embodiments and the drawings are incorporated in this specification and constitute a part of this specification. The drawings illustrate the embodiments and, together with the description, illustrate the principles of the invention. Many of the intended advantages of other embodiments and embodiments will be readily appreciated, as they become better understood by reference to the following detailed description. The elements of the drawings are not necessarily to scale. The same reference numbers refer to corresponding similar parts.

FIG. 1 is a schematic view illustrating a light path of a light source device coated with a phenyl-based silica gel layer in the remote excitation mode described in the background art.

FIG. 2 is a schematic view illustrating a light path of a light source device of an embodiment of the present application.

FIG. 3 is a schematic structural view of a light source device of an embodiment of the present application.

FIG. 4 is a flow chart of a manufacturing method of LED light source device of an embodiment of the application.

### EXPLANATION OF THE REFERENCE NUMBERS

1—base, 2—driving circuit, 3—heat conductive plate, 4—blue light chip, 5—transparent colloid, 6—heat dissipation device, 7—remote phosphor lampshade.

### DETAILED DESCRIPTION

The present application will be further described in detail below with reference to embodiments, but the embodiments of the present application are not so limited.

It is well known that when light is incident from one substance into another, refraction or reflection occurs, and as long as certain conditions are met, total reflection occurs without refraction.

According to the critical angle calculation formula: sin α=n1/n2 (α is the critical angle, n1 and n2 are refractive indices of different substances respectively), n1 represents air having a refractive index of 1, and n2 represents phenyl-based silica gel (having a refractive index of 1.42) or phenyl-based silica gel (having a refractive index of 1.58).

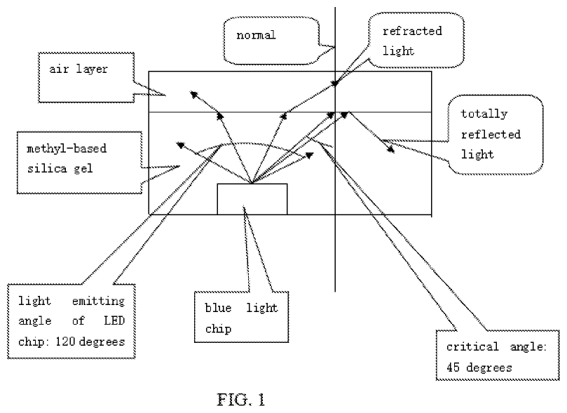

Firstly, the critical angle of phenyl-based silica gel is analyzed: sin α=n1/n2=1/1.42=0.704, α≈45°, as shown in FIG. 1. It can be analyzed from FIG. 1 that total reflection will occur when the incident angle exceeds 45°, so that partial light will not be refracted out of the phenyl-based silica gel layer, but reflected back to the chip surface or the substrate surface. It can be obtained by calculation that the light output angle of the LED chip is about 120° in case no total reflection occurs. However, the normal light output angle after the phenyl-based silica gel layer is coated is only about 90°, and light of about 30° range is totally reflected. Therefore, the blue light output efficiency of the chip is reduced by about 30/120*100%=25%. Similarly, if phenyl-based silica gel is used, the critical angle thereof is: sin α=n1/n2=1/1.58=0.632, α≈40°. Therefore, the normal light output angle after the phenyl-based silica gel layer is coated is only 80°, and light of about 40° is totally reflected. The blue light output efficiency of the chip is reduced by about 40/120*100%=33.3%. The results of actual tests are consistent with the theoretical values described above.

In summary, the reason for the decrease in the light output efficiency after methyl-based silica gel or phenyl-based silica gel is coated is that partial blue light is totally reflected.

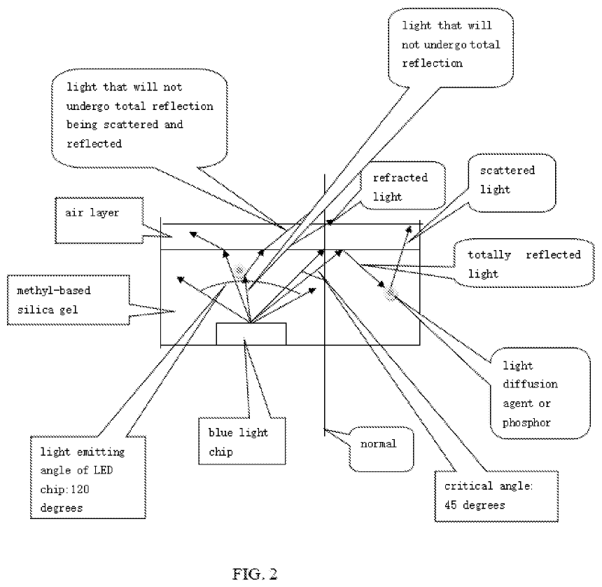

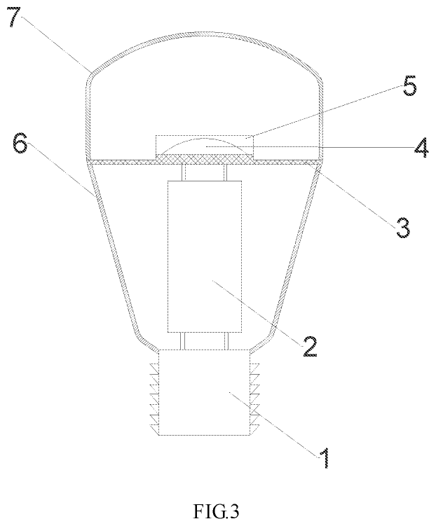

FIG. 2 is a schematic view of light route of an light source device of an embodiment of the application. FIG. 3 is a structural schematic view of a lamp of an embodiment of the application.

### Embodiment 1

A novel colloid is formed by blending light diffusion agent at an amount of 2% to 8% by weight into methyl-based silica gel or phenyl-based silica gel. The light diffusion agent has a particle diameter D50 of less than 10 μm and a refractive index of 1.5 to 1.7.

This colloid is coated on the blue light chip fixed in the form of SMD or COB as described above, instead of the above-mentioned methyl-based silica gel or phenyl-based silica gel, to form a novel LED light source device.

This is for the purpose of scattering blue light to reduce total reflection. The experimental results show that the light output efficiency of a light source device to which the colloid described in this embodiment is applied reaches more than 92% of that of a light source device not coated with any colloid (that is, the blue light chip is exposed), and is 20% higher than that of a light source device coated with the methyl-based silica gel or phenyl-based silica gel.

### Embodiment 2

A mixed powder of a light diffusion agent (having a particle diameter D50 of less than 10 μm and a refractive index of 1.5-1.7) and an LED phosphor is blended into the methyl-based silica gel or the phenyl-based silica gel. The ratio of the light diffusion agent to the LED phosphor in the mixed powder can be set according to a required lamp color temperature (cool color or warm color). The mixed powder has a weight ratio of 2% to 8% in the methyl-based silica gel or phenyl-based silica gel to form a novel colloid.

This colloid is coated on the blue light chip fixed in the form of SMD or COB instead of the above-mentioned methyl-based silica gel or phenyl-based silica gel to form a novel LED light source device.

This can not only scatter blue light to reduce total reflection, but also enable blue light to excite the phosphor to emit light of different wavelengths. This design not only contributes to the improvement of the luminous efficiency of the entire LED lamp to which the LED light source device of this patent is applied, but also helps to flexibly set the needed color temperature of the lamp and to reduce the cost of the entire LED lamp. Due to the low proportion of the blended phosphor, there is no significant impact on the temperature of the LED light source device.

It can be seen from FIG. 2 that light totally reflected back onto the light diffusion agent or phosphor will be scattered again out of the colloid and enter the air layer. At the same time, light that may be totally reflected originally is scattered or refracted by the light diffusion agent before reaching the interface so that the incident angle is changed, which decreases the proportion of total reflection and greatly reduces occurrence of total reflection of the blue light or ray of light at the interface between the colloid and the air, thereby increasing the light output efficiency of the light source device.

The LED light source device made by coating and solidifying the colloid of Embodiment 1 and Embodiment 2 on the blue light chip fixed in the form of COB generally cannot be applied directly to ordinary lighting products. Such device design can be directly applied to general lighting only by virtue of a remote component (such as a lampshade) added with a phosphor.

FIG. 3 shows a luminaire in which an LED light source device (the blue light chip is fixed in the form of COB) of the present application is added with a remote phosphor lampshade. This luminaire comprises a base 1, a driving circuit 2, a heat conductive plate (or a substrate) 3, a blue light chip 4, a colloid 5, a heat dissipation device 6 and a remote phosphor lampshade 7, which is installed in the same manner as ordinary lamps. Therein, the heat conductive plate 3, the blue light chip 4 and the colloid 5 form a LED light source device.

The base 1, the heat dissipation device 6 and the remote phosphor lampshade 7 are combined into a housing of the lamp sequentially from bottom to top, which includes a cavity. The driving circuit 2, the heat conductive plate 3, and the blue light chip 4 are installed in the cavity from bottom to top. The blue light chip 4 is fixed on the heat conductive plate 3, and the blue light chip 4 and the heat conductive plate 3 are coated with the colloid 5. The driving circuit 2 is fixed on the base 1 which has a circuit therein. The incoming end of the driving circuit is connected to the power supply outgoing end of the base 1 and is connected to an external power supply through the base 1, and the outgoing end thereof is connected to the lower end surface of the heat conductive plate 3.

The heat conductive plate 3 is a heat conductive metal plate or a heat conductive ceramic substrate. The size of the heat conductive plate 3 is the same as the cross section of the cavity. After installation, a sealing member is formed. The height of the heat dissipation device 6 is determined according to the size of the driving circuit 2 to ensure that the heat conductive plate 3 is connected to the heat dissipation device 6 after installation. The blue light chip 4 is directly placed on the upper end surface of the heat conductive plate 3 and subjected to heat treatment until the blue light chip 4 is firmly fixed on the heat conductive plate 3. Then, an electrical connection is directly established between the blue light chip 4 and the heat conductive plate 3 by wire bonding. The heat of the blue light chip 4 can be dissipated through the heat conductive plate 3 and the heat dissipation device 6.

FIG. 4 shows a flow chart of a manufacturing method of LED light source device of an embodiment of this application. As shown in FIG. 4, the manufacturing method comprises the following steps:

fixing a blue light chip on a substrate in the form of SMD or COB,

coating a colloid on the blue light chip, which colloid comprising silica gel base and light diffusion agent at an amount of 2% to 8% by weight, and

solidifying the colloid to form an LED light source device.

What are stated above are merely preferred embodiments of the present application, and are not intended to limit the technical scope of the present application. Therefore, any minor modifications, equivalent variations, and modifications made to the above embodiments based on the technical essence of the present application still fall within the protection scope of the present application.

What is claimed is:

1-5. (canceled)

6. An LED light source device, comprising a blue light chip fixed on a substrate and a colloid solidified on the blue light chip, and the colloid comprises silica gel base and light diffusion agent at an amount of 2% to 8% by weight.

7. The LED light source device according to claim 6, therein the light diffusion agent has a particle diameter D50 of less than 10 μm and a refractive index of 1.5 to 1.7.

8. The LED light source device according to claim 6, therein the silica gel base comprises methyl-based silica gel or phenyl-based silica gel.

9. The LED light source device according to claim 6, therein a remote phosphor lampshade is provided outside the LED light source device.

10. An LED light source device, comprising a blue light chip fixed on a substrate and a colloid solidified on the blue light chip, and the colloid is made by silica gel base and a mixed powder at an amount of 2% to 8% by weight, the mixed powder comprising light diffusion agent and LED phosphor.

11. The LED light source device according to claim 10, therein the light diffusion agent has a particle diameter D50 of less than 10 μm and a refractive index of 1.5 to 1.7.

12. The LED light source device according to claim 10, therein the silica gel base comprises methyl-based silica gel or phenyl-based silica gel.

13. The LED light source device according to claim 10, therein a remote phosphor lampshade is provided outside the LED light source device.

14. A method for manufacturing an LED light source device, comprising the following steps:
fixing a blue light chip on a substrate in the form of SMD or COB,
coating a colloid on the blue light chip, which colloid comprising silica gel base and light diffusion agent at an amount of 2% to 8% by weight, and
solidifying the colloid to form an LED light source device.
